(19) United States
(12) Patent Application Publication
(10) Pub. No.: US 2025/0079417 A1
(43) Pub. Date: Mar. 6, 2025

(54) HIGH-REJECTION/HIGH-ISOLATION MODULE WITH EXTERNAL GROUND RE-REFERENCING STRUCTURE

(71) Applicant: Qorvo US, Inc., Greensboro, NC (US)

(72) Inventors: Kelly M. Lear, Longwood, FL (US); Lawrence A. Carastro, Windermere, FL (US)

(21) Appl. No.: 18/813,222

(22) Filed: Aug. 23, 2024

Related U.S. Application Data
(60) Provisional application No. 63/645,376, filed on May 10, 2024.
(60) Provisional application No. 63/580,794, filed on Sep. 6, 2023.

(51) Int. Cl. H01L 25/16; H01L 21/50; H01L 23/538

(52) U.S. Cl. CPC H01L 25/16; H01L 21/50; H01L 23/5386; H10D 1/20; H10D 1/68

(57) ABSTRACT

Radio frequency (RF) circuitry and methods of operating the same are disclosed. In some embodiments, the RF circuitry includes a circuit package. The circuit package includes a package substrate, a first RF circuit, and a second RF circuit. The package substrate has a package body and a metallic structure integrated within the package body, wherein the metallic structure has a ground plane that defines a gap. The first RF circuit is cascaded with the second RF circuit such that a section of a RF signal line that connects the first RF circuit to the second RF circuit is directly above the gap in the ground plane. The circuit package may be mounted on a printed circuit (PC) board. The gap allows the electric field of the trace that connects the RF circuits to see the ground plane outside of the package, reducing the impact of the common ground inductance.

### RELATED APPLICATIONS

This application claims the benefit of provisional patent application Ser. No. 63/645,376, filed May 10, 2024, and provisional patent application Ser. No. 63/580,794, filed Sep. 6, 2023, the disclosures of which are hereby incorporated herein by reference in their entireties.

### FIELD OF THE DISCLOSURE

This disclosure relates generally to cascaded radio frequency (RF) circuits and methods of manufacturing the same.

### BACKGROUND

Radio frequency (RF) circuits are often cascaded to achieve specific performance requirements in RF systems. RF circuits that are cascaded are often RF amplification circuits, RF filters, or combinations of RF amplification circuits and RF filters. Cascading is particularly useful with RF filters. Cascading RF filters allows for the creation of complex filtering responses that may not be achievable with a single filter. By combining multiple filters in cascade, RF designers can tailor the overall frequency response to meet stringent specifications such as bandwidth, selectivity, and out-of-band rejection. Each filter circuit can be optimized for different frequency bands or attenuation characteristics, thus enabling finer control over signal processing. Additionally, cascading filters can help mitigate unwanted signal interference and noise, which improves the overall signal quality and reliability of RF systems. This modular approach to filtering also offers scalability and flexibility in system design, allowing for adaptation to diverse RF applications, ranging from wireless communication to radar systems. Unfortunately, packaging a long cascade of circuits (i.e., RF filters) also introduces parasitic impedances, such as common ground inductance, that can result in degradation of performance. What is needed are techniques that reduce the parasitic impedances that often result from packaging a significant amount of circuitry in one package.

### SUMMARY

In some embodiments, radio frequency (RF) circuitry includes a circuit package that includes: a package substrate having a package body and a metallic structure integrated with the package body, wherein the metallic structure has a ground plane and the ground plane defines a gap; a first RF circuit; and a second RF circuit, wherein: the first RF circuit is cascaded with the second RF circuit such that a section of an RF signal line connects the first RF circuit to the second RF circuit; and wherein the section of the RF signal line is directly above the gap in the ground plane. In some embodiments, the RF circuitry includes a printed circuit (PC) board, wherein: the ground plane is a first ground plane; the PC board defines a second ground plane; and the gap in the first ground plane is directly above the second ground plane in the PC board. In some embodiments, the PC board has a PC board body; the circuit package is mounted over a top surface of the PC board body; and the second ground plane is integrated with the PC board body. In some embodiments, the metallic structure defines a plurality of metallic layers integrated with the package body, wherein the section of the RF signal line is formed in a first metallic layer of the plurality of metallic layers and the first ground plane is formed in a second metallic layer of the plurality of metallic layers, and wherein the first metallic layer is positioned above the second metallic layer. In some embodiments, the package body defines a bottom surface that is positioned above the top surface of the PC board body; the second metallic layer is mounted on the bottom surface of the package body; and the first metallic layer is positioned within the package body. In some embodiments, the first metallic layer is in a bottom two thirds of the package body. In some embodiments, the first metallic layer is a bottom most metallic layer that is within the package body. In some embodiments, the RF circuitry further includes a solder layer between the package substrate and the PC board, wherein the solder layer mounts the package substrate to the PC board. In some embodiments, a width of the gap is equal to a length of the section of the RF signal line. In some embodiments, the RF circuitry includes a dielectric material that fills the gap in the ground plane.

In some embodiments, a user element includes RF circuitry, the RF circuitry includes a circuit package that includes: a package substrate having a package body and a metallic structure integrated with the package body, wherein the metallic structure has a ground plane and the ground plane defines a gap; a first RF circuit; and a second RF circuit, wherein the first RF circuit is cascaded with the second RF circuit such that a section of an RF signal line connects the first RF circuit to the second RF circuit, and wherein the section of the RF signal line is directly above the gap in the ground plane. In some embodiments, the RF circuitry further includes a PC board, wherein: the ground plane is a first ground plane; the PC board defines a second ground plane; and the gap in the first ground plane is directly above the second ground plane in the PC board. In some embodiments, the PC board has a PC board body that defines a top surface; the circuit package is mounted over the top surface of the PC board body; and the second ground plane is mounted to the top surface of the PC board body. In some embodiments, the metallic structure defines a plurality of metallic layers integrated with the package body, wherein the section of the RF signal line is formed in a first metallic layer of the plurality of metallic layers and the first ground plane is formed in a second metallic layer of the plurality of metallic layers, and wherein the first metallic layer is positioned above the second metallic layer. In some embodiments, the package body defines a bottom surface that is positioned above the top surface of the PC board body; the second metallic layer is mounted on the bottom surface of the package body; and the first metallic layer is positioned within the package body. In some embodiments, the first metallic layer is in a bottom two thirds of the package body. In some embodiments, the first metallic layer is a bottom most metallic layer that is within the package body. In some embodiments, the RF circuitry further includes a solder layer between the package substrate and the PC board, wherein the solder layer mounts the package substrate to the PC board. In some embodiments, a width of the gap is equal to a length of the section of the RF signal line.

In some embodiments, a method of manufacturing an RF package includes: forming a package substrate having a package body and a ground plane; forming a gap in the ground plane; forming a first RF circuit; and forming a second RF circuit, wherein the first RF circuit is cascaded with the second RF circuit such that a section of an RF signal line connects the first RF circuit to the second RF circuit, and wherein the section of the RF signal line is directly above the gap in the ground plane.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates radio frequency (RF) circuitry, in accordance with some embodiments;

FIG. 2 illustrates a package substrate, a solder layer, and a printed circuit (PC) board stacked on each other, in accordance with some embodiments;

FIG. 3 illustrates an RF circuit cascaded to another RF circuit, in accordance with some embodiments;

FIG. 4A and FIG. 4B illustrate an embodiment of a package substrate shown in FIG. 1, in accordance with some embodiments;

FIG. 5 illustrates a frequency response of the cascaded RF circuits shown in FIG. 4A and FIG. 4B without a gap in a ground plane as well as a frequency response of the cascaded RF circuits shown in FIG. 4A and FIG. 4B with the gap, in accordance with some embodiments;

FIG. 6 illustrates a flow diagram describing a method of manufacturing RF circuitry, in accordance with some embodiments; and

FIG. 7 illustrates a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Some radio frequency (RF) applications may require more rejection/greater than 60 dB at low gigahertz or higher frequencies. Disclosed are techniques for cascading RF circuits, in particular, RF filters that provide the required rejection within a single circuit package. Two high-rejection filters/high-isolation channel devices in one package would typically have their rejection limited by the common ground inductance of the circuit package. Two separate circuit packages may be used on a printed circuit (PC) board, but will often not cascade ideally (i.e., twice the passband loss with the same return loss and twice the rejection). In this disclosure, two or more RF circuits (e.g., RF amplification circuits, RF filters, etc.) are cascaded. In this disclosure, a section of an RF signal line (or sections of the RF signal lines) that connects the different RF circuits is provided above a gap in a ground plane positioned in the circuit package. For example, when two RF filters are cascaded, the section of the RF signal line connecting the two RF filters is provided directly above a gap in the ground plane of the circuit package. The circuit package may then be mounted on a PC board. Each of the RF filters may have approximately 25 dB to 90 dB of rejection. The gap in the ground plane of the circuit package allows the section of the RF signal line to utilize the ground plane of the PC board (external to the subject package) as a reference. This design allows for both of the cascaded RF circuits to be formed in a single circuit package while reducing the common ground inductance presented to the section of the RF signal line that connects the two cascaded RF circuits.

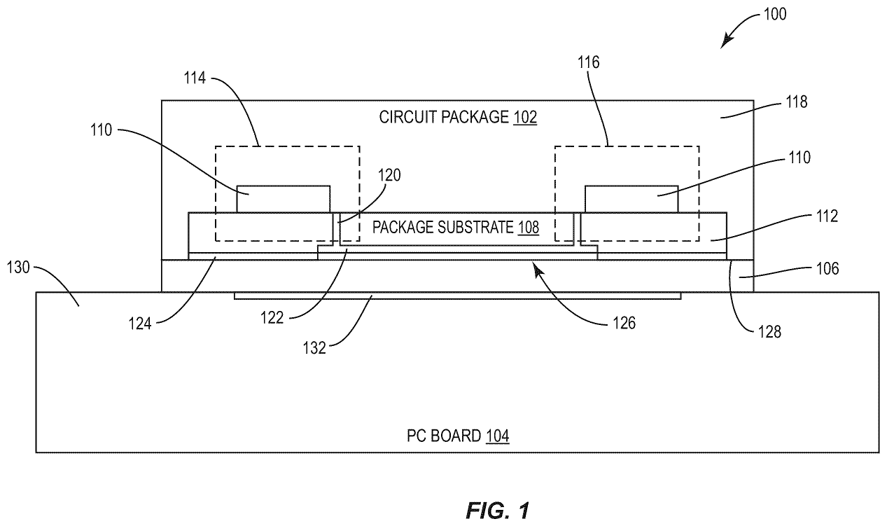

FIG. 1 illustrates RF circuitry 100, in accordance with some embodiments.

The RF circuitry 100 includes a circuit package 102 and a PC board 104. The circuit package 102 is mounted on the PC board 104 by a solder layer 106. The circuit package 102 includes a package substrate 108 (e.g., a laminate). In FIG. 1, the circuit package 102 is an integrated circuit (IC) package that includes IC circuits formed in semiconductor substrates 110 (i.e., a semiconductor die) that are mounted on the package substrate 108. It should be noted that, in other embodiments, the circuit package 102 is not an IC package because the circuit package 102 may not include a semiconductor substrate (like the semiconductor substrates 110), but rather may simply include circuits formed with the package substrate 108. Furthermore, in other embodiments, another type of package substrate (e.g., ceramic) is used other than laminate in the package substrate 108. In FIG. 1, the package substrate 108 includes a metallic structure (not fully shown in FIG. 1) and a package body 112. The semiconductor substrates 110 are mounted on the package body 112 and interconnected by the metallic structure formed with the package body 112. The metallic structure formed with the package body 112 also forms electronic components such as conductors, resistors, inductors, and capacitors that form part of the circuitry. Different types of RF circuits can be formed with the metallic structure formed with the package body 112, such as RF filters. Different types of RF circuits can be formed with the metallic structure and the semiconductor substrates 110, such as power amplification (PA) circuits. The package substrate 108 and the semiconductor substrates 110 are encapsulated in a dielectric 118.

In this embodiment, the circuit package 102 includes an RF circuit 114 and an RF circuit 116. In some embodiments, the RF circuit 114 is an RF filter or a PA circuit. In some embodiments, the RF circuit 116 is an RF filter or a PA circuit. In other embodiments, the RF circuit 114 and/or the RF circuit 116 may include a low noise amplifier (LNA), a PA, a coupler, or another type of circuit. The RF circuit 114 is cascaded with the RF circuit 116. As such, an RF signal line 120 is provided through the RF circuit 114 and the RF circuit 116 since an RF signal is passed from the RF circuit 114 and through the RF circuit 116 or from the RF circuit 116 and through the RF circuit 114. In one example, both the RF circuit 114 and the RF circuit 116 are both RF filters. Accordingly, the RF circuit 114 filters the RF signal and then passes the RF signal to the RF circuit 116, which also filters the RF signal. The metallic structure formed with the package body 112 includes a section 122 of the RF signal line 120 that connects the RF circuit 114 to the RF circuit 116. In some embodiments, the section 122 of the RF signal line 120 is positioned in the bottom two thirds of the package body 112. In some embodiments, the section 122 of the RF signal line 120 is positioned in the bottom half of the package body 112. In some embodiments, the section 122 of the RF signal line 120 is an RF transmission line. While the embodiment in FIG. 1 only shows a single section 122, it should be noted that, in other embodiments, there may be multiple sections 122 (e.g., if the RF signal is a differential signal and, thus, there are two RF signal lines used to carry the RF signal).

The metallic structure formed with the package body 112 also includes a continuous ground plane 124. The ground plane 124 is configured to define a ground voltage and is positioned below the section 122 of the RF signal line 120 that connects the RF circuit 114 to the RF circuit 116. However, the large, continuous ground plane 124 (without gaps) can result in excessive common ground inductance in the combined sections 114 and 116. In order to reduce the impact of the common inductance caused by the ground plane 124, the circuitry is broken up into lesser sections that would not be limited by the common ground inductance of the continuous ground plane 124 by the gap 126. The section 122 of the RF signal line is directly above the gap 126 in the ground plane 124. In this embodiment, the ground plane 124 is formed on a bottom surface 128 of the package body 112. Also in this embodiment, the gap 126 is filled with the dielectric material 118.

The circuit package 102 is mounted on the PC board 104 by the solder layer 106. The solder layer 106 provides mechanical stability to attach the circuit package 102 to the PC board 104. Furthermore, the solder layer 106 provides an electrical connection between connection nodes of the circuit package 102 and the PC board 104. The solder layer 106 may include Eutectic Tin-Lead (Sn—Pb), Lead-Free Solder Alloys, Tin-Silver-Copper (Sn—Ag—Cu), Tin-Copper (Sn—Cu), Tin-Bismuth (Sn—Bi), Solder Paste, Solder Balls (for Ball Grid Array packages), Solder Preforms, and/or any other suitable soldering material. It may include other conductive materials, such as silver conductive epoxy. The selection of solder material depends on various factors, such as the specific requirements of the application, regulatory compliance, assembly process capabilities, and reliability considerations.

The PC board 104 includes a PC board body 130 (e.g., a laminate) and a metallic structure (not completely shown in FIG. 1). The metallic structure is formed to provide connections between different circuit packages, such as the circuit package 102. The metallic structure of the PC board 104 includes a ground plane 132. In this embodiment, the ground plane 132 is positioned in a top most layer of the metallic structure of the PC board 104. The gap 126 in the ground plane 124 is directly above the ground plane 132 in the PC board 104. The gap 126 allows for there to be a reduced distance from the section 122 of the RF signal line 120 and a ground plane, which, in this case, is the ground plane 132. As a result, the common ground inductance of the section 122 of the RF signal line 120 is reduced, as there is a reduced distance between the section 122 of the RF signal line 120 and the ground plane 132 than there would be without the gap 126.

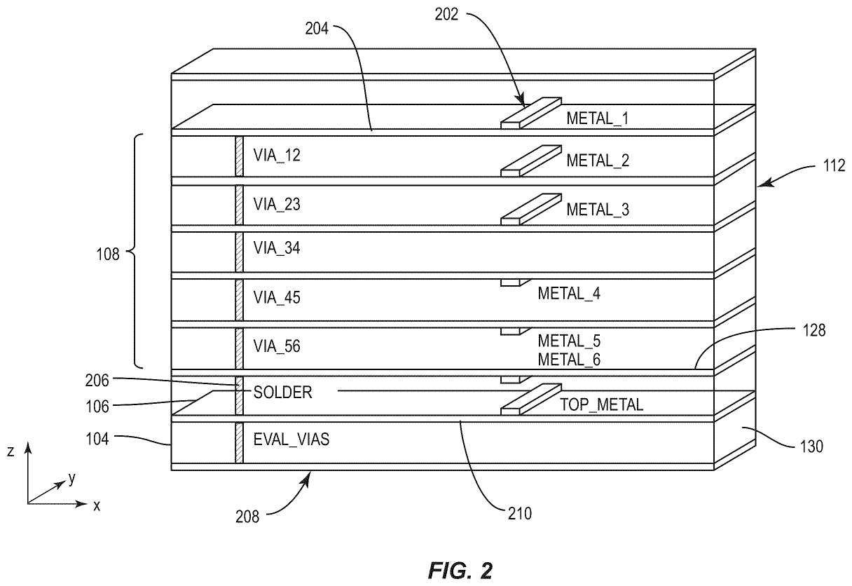

FIG. 2 is the package substrate 108, the solder layer 106, and the PC board 104 stacked on each other, in accordance with some embodiments.

The direction of stacking defines a vertical direction parallel to a Z-axis. A first horizontal direction is defined as orthogonal to the vertical direction and is parallel to an X-axis. A second horizontal direction is defined as orthogonal to both the vertical direction and the first horizontal direction. The second horizontal direction is parallel to a Y-axis.

The package substrate 108 includes the package body 112 formed from layers of a laminate that are stacked in the vertical direction over one another. A metallic structure 202 is formed from metallic layers and metallic via layers that connect the metallic layers. In this embodiment, the metallic structure 202 includes six metallic layers. If a variable M represents an integer from 1-6, each metallic layer is represented in the format “METAL_M” and are ordered from top to bottom. It should be noted that other embodiments of the package body 112 may have any number of metallic layers other than six and six metallic layers is simply exemplary. Each of the metallic via layers include metallic vias that connect structures between two metallic layers, one metallic layer on top of the via layer and one metallic layer below the via layer. Thus, if a variable T represents an integer 1-6 and a variable B represents an integer of 1-6, then each metallic via layer is represented in the format “VIA_TB,” where T corresponds to the integer for the metallic layer on top of the via layer and B corresponds to the integer for the metallic layer below the via layer.

In this embodiment, the package body 112 includes a top surface 204, which is the highest surface relative to the vertical direction of the package body 112. A metallic layer METAL_1 is formed on the top surface 204 of the package body 112. The metallic layers METAL_2-METAL_5 are formed internally to the package body 112. The package body 112 includes the bottom surface 128, which is the lowest surface relative to the vertical direction of the package body 112. The metal layer METAL_6 is formed on the bottom surface 128. The ground plane 124 (see FIG. 1) is formed in the metal layer METAL_6 and the gap 126 (see FIG. 1) would result in a metal void in the metal layer METAL_6.

Below the bottom surface 128 and the metal layer METAL_6 is the solder layer 106. The solder layer 106 includes solder vias 206 that connect metallic components in the package substrate 108 to the PC board 104. The solder layer 106 mounts the package substrate 108 to the PC board 104. The PC board 104 includes the PC board body 130 (which may be formed from a laminate or another suitable material). The PC board 104 includes a metallic structure 208. For the purpose of explanation, the metallic structure 208 of the PC board 104 is shown in a simplified manner. It should be noted that the metallic structure 208 may have any number of metallic layers and via layers. Also of relevance to this disclosure, the PC board body 130 defines a top surface 210, which is the highest surface of the PC board body 130 relative to the vertical direction. A metal layer TOP_METAL is formed on the top surface 210 of the PC board body 130. The metal layer TOP_METAL is the top most metal of the PC board 104. The ground plane 132 (see FIG. 1) is formed by the metal layer TOP METAL and would be directly beneath the gap 126, as shown in FIG. 1.

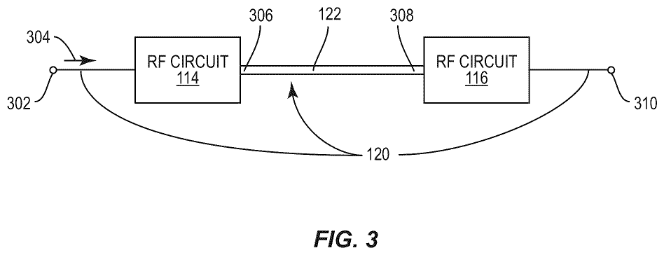

FIG. 3 illustrates the RF circuit 114 cascaded to the RF circuit 116, in accordance with some embodiments.

The RF circuit 114 includes an input node 302 for receiving an RF signal 304 and an output node 306 for transmitting the RF signal 304 after manipulation by the RF circuit 114. Similarly, the RF circuit 116 includes an input node 308 for receiving the RF signal 304 and an output node 310 for transmitting the RF signal 304 after manipulation by the RF circuit 116. Since the RF circuit 114 is cascaded to the other RF circuit 116, the output node 306 of the RF circuit 114 is connected to the input node 308 of the RF circuit 116 in a sequential configuration so that the RF signal 304 passes from the output node 306 to the input node 308, effectively creating a chain of the RF circuits 114, 116. Cascading the RF circuits 114, 116 is a technique used in RF design to achieve desired signal processing, amplification, or filtering functions. Some common applications include RF communication systems, radar systems, and RF test equipment. In this embodiment, the section 122 of the RF signal line 120 connects the output node 306 of the RF circuit 114 to the input node 308 of the RF circuit 116. The section 122 is provided in one of the metal layers METAL_3-METAL_5 (see FIG. 2), since the section 122 is in the bottom two thirds of the package body 112 (see FIG. 1). In some embodiments, the section 122 is provided in either the metal layer METAL_4 or the metal layer METAL_5, since the section 122 is in the bottom half of the package body 112. In some embodiments, the section 122 is provided in the metal layer METAL_5, since the section 122 is in the bottom most metallic layer that is within the package body 112.

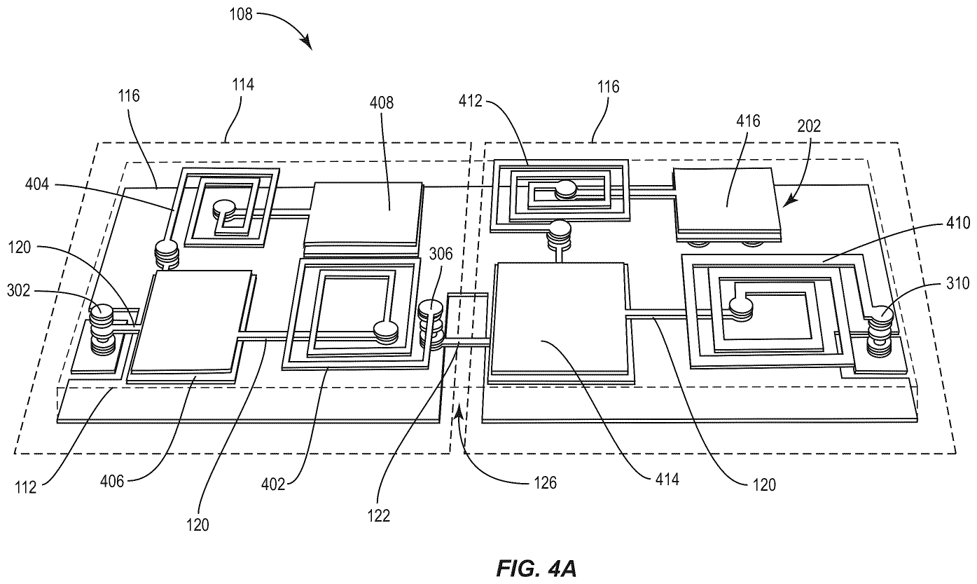

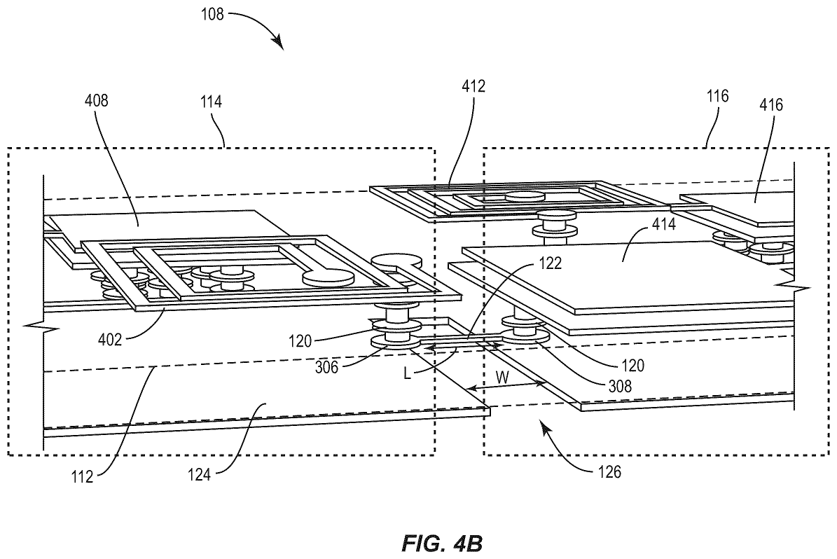

FIG. 4A and FIG. 4B are embodiments of the package substrate 108 shown in FIG. 1, in accordance with some embodiments.

The package substrate 108 includes an example of the RF circuit 114 (discussed in FIG. 1 and FIG. 3) and the RF circuit 116 (discussed in FIG. 1 and FIG. 3). The package substrate 108 includes an example of the package body 112 and the metallic structure 202. In this embodiment, the RF circuit 114 is an RF filter and the RF circuit 116 is an RF filter that are cascaded to one another. In other embodiments, one or both of the RF circuits 114, 116 are RF amplification circuits. In this embodiment, the RF circuit 114 and the RF circuit 116 are formed entirely from the metallic structure 202. In other embodiments, one or both of the RF circuits 114, 116 may also include semiconductor dies that are mounted on the package substrate 108. In some embodiments, the semiconductor dies have power amplification circuitry, surface acoustic wave (SAW) resonators, bulk acoustic wave (BAW) resonators, and/or the like.

The RF signal line 120 extends through the RF circuit 114 and the RF circuit 116. More specifically, the RF circuit 114 includes the input node 302 and the output node 306, as described above in FIG. 3. The RF circuit 116 includes the input node 308 and the output node 310, as described above in FIG. 3. The output node 306 of the RF circuit 114 is directly connected to the input node 308 of the RF circuit 116 by the section 122 of the RF signal line 120.

With respect to the RF circuit 114, the RF circuit 114 includes inductors 402, 404 and capacitors 406, 408. The inductors 402, 404 are formed by the metal layer METAL_1 (see FIG. 2) while the capacitors 406, 408 are formed by planes in the metal layer METAL_2 and the metal layer METAL_3 (see FIG. 2). The capacitor 406 and the inductor 402 are connected in series and the inductor 404 and the capacitor 408 are connected in shunt. The capacitor 406 and the inductor 402 are connected in series within the RF signal line 120 while the inductor 404 and the capacitor 408 are connected in shunt with respect to the RF signal line 120. The section 122 is positioned in the metal layer METAL_5 (see FIG. 2).

With respect to the RF circuit 116, the RF circuit 116 includes inductors 410, 412 and capacitors 414, 416. The inductors 410, 412 are formed by the metal layer METAL_1 while the capacitors 414, 416 are formed by planes in the metal layer METAL_2 and the metal layer METAL_3. The capacitor 414 and the inductor 410 are connected in series and the inductor 412 and the capacitor 416 are connected in shunt. The capacitor 414 and the inductor 410 are connected in series within the RF signal line 120 while the inductor 412 and the capacitor 416 are connected in shunt with respect to the RF signal line 120.

The ground plane 124 is positioned in the metal layer METAL_6 (see FIG. 2). As shown, the ground plane 124 defines the gap 126, in which the section 122 of the RF signal line 120 is directly above the gap 126 in the ground plane 124. In some embodiments, the dielectric material 118 (see FIG. 1) fills the gap 126. In this embodiment, a width W (relative to the X axis in FIG. 2) of the gap 126 is equal to a length L (relative to the X axis in FIG. 2) of the section 122 of the RF signal line 120. As mentioned above, the ground plane 132 (see FIG. 1) of the PC board 104 (see FIG. 1) is positioned directly below the gap 126 when the package substrate 108 (see FIG. 1) is mounted on the PC board 104. In this manner, the common ground inductance of the entirety of the cascade of circuits 114 and 116 is reduced.

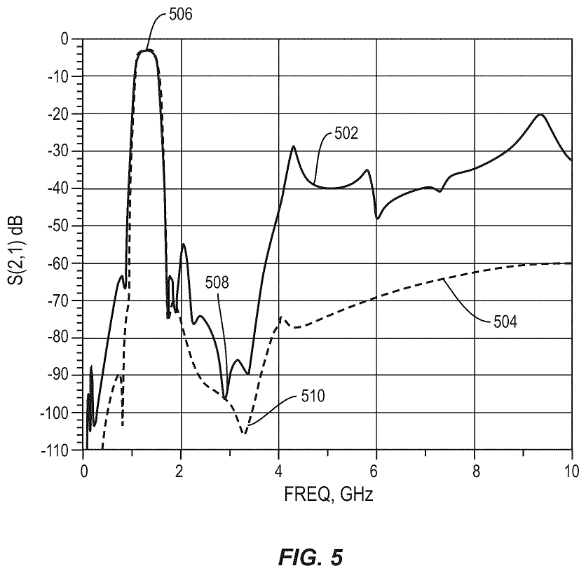

FIG. 5 illustrates a frequency response 502 (in particular, an (S(2,1)) response) of the cascaded RF circuits 114, 116 shown in FIG. 4A and FIG. 4B without the gap 126 (see FIG. 1) in the ground plane 124 (see FIG. 1) and a frequency response 504 (in particular, an (S(2,1)) response) of the cascaded RF circuits 114, 116 with the gap 126 (as actually shown in FIG. 4A and FIG. 4B), in accordance with some embodiments.

Both the frequency response 502 and the frequency response 504 define a same passband 506. However, the frequency response 502 defines a stop band 508 and the frequency response 504 defines a stop band 510. While each of the RF circuits 114, 116 have approximately 25-90 dB of rejection, the common ground inductance caused by the ground plane 124 limits the rejection of the stop band 508 due to the common ground inductance between the section 122 (see FIG. 1) and the ground plane 124. Thus, to reduce this common ground inductance to a level that will not degrade the filter performance, the gap 126 is provided, splitting the filter into two (or potentially more) different sections that are less limited by the common ground inductance they have, so the stop band 510 provides higher out-of-band rejection. This reduction in performance from common ground inductance from the section 122 is due to the gap 126 in the ground plane 124.

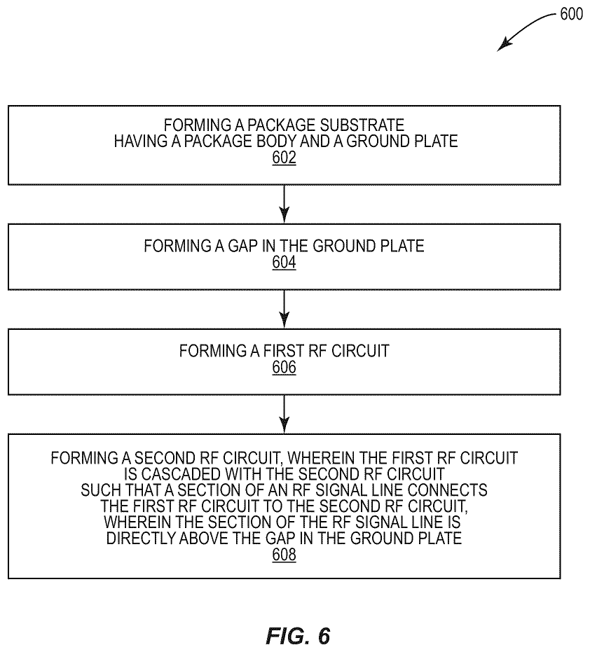

FIG. 6 illustrates a flow diagram 600 describing a method of manufacturing RF circuitry, in accordance with some embodiments.

In some embodiments, the RF circuitry manufactured by the flow diagram 600 is the RF circuitry 100 shown in FIG. 1. The flow diagram 600 includes blocks 602-608. It should be noted that the blocks 602-608 do not have to be performed in the order shown in FIG. 6. Furthermore, it should be noted that one or more of the blocks 602-608 may be performed at different times or simultaneously. Flow begins at block 602.

At block 602, a package substrate is formed, the package substrate having a package body and a ground plane. An example of the package substrate is the package substrate 108 shown in FIG. 1 and FIG. 2. An example of the package body is the package body 112 shown in FIG. 1, FIG. 2, FIG. 4A, and FIG. 4B. An example of the ground plane is the ground plane 124 shown in FIG. 1, FIG. 4A, and FIG. 4B. Flow then proceeds to block 604.

At block 604, a gap is formed in the ground plane. An example of the gap is the gap 126 shown in FIG. 1, FIG. 4A, and FIG. 4B. Flow then proceeds to block 606. Note that the blocks 602, 604 may be performed simultaneously in some embodiments.

At block 606, a first RF circuit is formed. An example of the first RF circuit is either the RF circuit 114 or the RF circuit 116 shown in FIG. 1, FIG. 3, FIG. 4A, and FIG. 4B. Flow then proceeds to block 608. Note that block 606 may be performed simultaneously with one or more of the blocks 602, 604 in some embodiments.

At block 608, a second RF circuit is formed, wherein the first RF circuit is cascaded with the second RF circuit such that a section of RF signal line connects the first RF circuit to the second RF circuit, wherein the section of the RF signal line is directly above the gap in the ground plane. An example of the second RF circuit is either the RF circuit 114 or the RF circuit 116 shown in FIG. 1, FIG. 3, FIG. 4A, and FIG. 4B. An example of the section is the section 122 shown in FIG. 1, FIG. 3, FIG. 4A, and FIG. 4B, in accordance with some embodiments. Note that block 608 may be performed simultaneously with one or more of the blocks 602, 604, 606 in some embodiments.

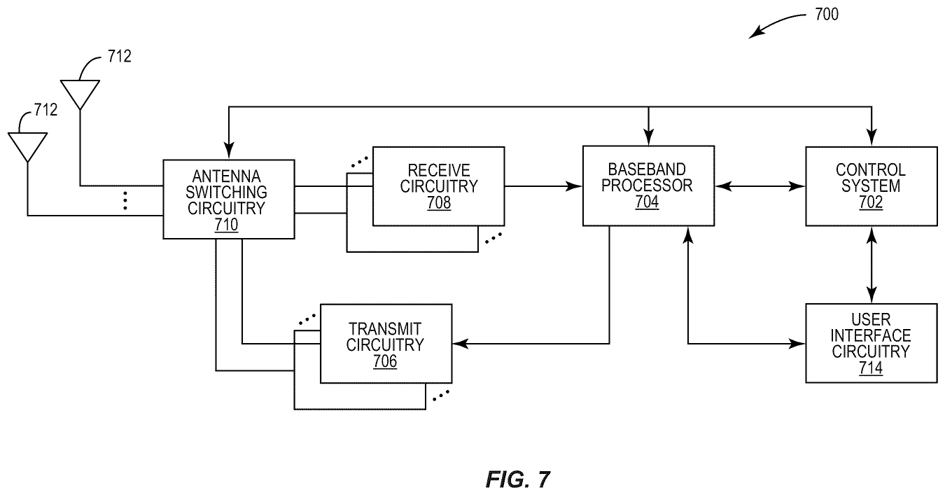

With reference to FIG. 7, the concepts described above may be implemented in various types of user elements 700, such as mobile terminals, smart watches, tablets, computers, navigation devices, access points, and like wireless communication devices that support wireless communications, such as cellular, wireless local area network (WLAN), Bluetooth, and near field communications. The user element 700 will generally include a control system 702, a baseband processor 704, transmit circuitry 706, receive circuitry 708, antenna switching circuitry 710, multiple antennas 712, and user interface circuitry 714. In a non-limiting example, the control system 702 may be a field-programmable gate array (FPGA) or an application-specific integrated circuit (ASIC). In this regard, the control system 702 may include at least a microprocessor(s), an embedded memory circuit(s), and a communication bus interface(s). The receive circuitry 708 receives radio frequency signals via the antennas 712 and through the antenna switching circuitry 710 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC). The RF circuitry described above in FIG. 1-FIG. 4B is implemented in the user element 700.

The baseband processor 704 processes the digitized received signal to extract the information or data bits conveyed in the received signal. This processing typically comprises demodulation, decoding, and error correction operations, as will be discussed in greater detail below. The baseband processor 704 is generally implemented in one or more digital signal processors (DSPs) and ASICs.

For transmission, the baseband processor 704 receives digitized data, which may represent voice, data, or control information, from the control system 702, which it encodes for transmission. The encoded data is output to the transmit circuitry 706, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 712 through the antenna switching circuitry 710. The multiple antennas 712 and the replicated transmit and receive circuitries 706, 708 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

What is claimed is:

1. Radio Frequency (RF) circuitry, the RF circuitry comprising:
an circuit package comprising:
a package substrate having a package body and a metallic structure integrated with the package body, wherein the metallic structure has a ground plane and the ground plane defines a gap;
a first RF circuit; and
a second RF circuit, wherein:
the first RF circuit is cascaded with the second RF circuit such that a section of an RF signal line connects the first RF circuit to the second RF circuit, wherein the section of the RF signal line is directly above the gap in the ground plane.

2. The RF circuitry of claim 1, further comprising a printed circuit (PC) board, wherein:
the ground plane is a first ground plane;
the PC board defines a second ground plane; and
the gap in the first ground plane is directly above the second ground plane in the PC board.

3. The RF circuitry of claim 2, wherein:
the PC board has a PC board body;
the circuit package is mounted over the top surface of the PC board body; and
the second ground plane is integrated with the PC board body.

4. The RF circuitry of claim 3, wherein the metallic structure defines a plurality of metallic layers integrated with the package body, wherein the section of the RF signal line is formed in a first metallic layer of the plurality of metallic layers and the first ground plane is formed in a second metallic layer of the plurality of metallic layers, wherein the first metallic layer is positioned above the second metallic layer.

5. The RF circuitry of claim 4, wherein:
the package body defines a bottom surface that is positioned above the top surface of the PC board body;
the second metallic layer is mounted on the bottom surface of the package body; and
the first metallic layer is positioned within the package body.

6. The RF circuitry of claim 5, wherein the first metallic layer is in a bottom two thirds of the package body.

7. The RF circuitry of claim 5, wherein the first metallic layer is a bottom most metallic layer that is within the package body.

8. The RF circuitry of claim 2, wherein the RF circuitry further comprises a solder layer between the package substrate and the PC board, wherein the solder layer mounts the package substrate to the PC board.

9. The RF circuitry of claim 1, wherein a width of the gap is equal to a length of the section of the RF signal line.

10. The RF circuitry of claim 1, further comprising a dielectric material that fills the gap in the ground plane.

11. A user element comprising radio frequency (RF) circuitry, the RF circuitry comprising:
a circuit package comprising:
a package substrate having a package body and a metallic structure integrated with the package body, wherein the metallic structure has a ground plane and the ground plane defines a gap;
a first RF circuit; and
a second RF circuit, wherein the first RF circuit is cascaded with the second RF circuit such that a section of an RF signal line connects the first RF circuit to the second RF circuit, wherein the section of the RF signal line is directly above the gap in the ground plane.

12. The user element of claim 11, wherein the RF circuitry further comprises a printed circuit (PC) board, wherein:
the ground plane is a first ground plane;
the PC board defines a second ground plane; and
the gap in the first ground plane is directly above the second ground plane in the PC board.

13. The user element of claim 12, wherein:
the PC board has a PC board body that defines a top surface;
the circuit package is mounted over the top surface of the PC board body; and
the second ground plane is mounted to the top surface of the PC board body.

14. The user element of claim 13, wherein the metallic structure defines a plurality of metallic layers integrated with the package body, wherein the section of the RF signal line is formed in a first metallic layer of the plurality of metallic layers and the first ground plane is formed in a second metallic layer of the plurality of metallic layers, wherein the first metallic layer is positioned above the second metallic layer.

15. The user element of claim 14, wherein:
the package body defines a bottom surface that is positioned above the top surface of the PC board body;
the second metallic layer is mounted on the bottom surface of the package body; and
the first metallic layer is positioned within the package body.

16. The user element of claim 15, wherein the first metallic layer is in a bottom two thirds of the package body.

17. The user element of claim 15, wherein the first metallic layer is a bottom most metallic layer that is within the package body.

18. The user element of claim 12, wherein the RF circuitry further comprises a solder layer between the package substrate and the PC board, wherein the solder layer mounts the package substrate to the PC board.

19. The user element of claim 11, wherein a width of the gap is equal to a length of the section of the RF signal line.

20. A method of manufacturing a radio frequency (RF) package, the method comprising:
forming a package substrate having a package body and a ground plane;
forming a gap in the ground plane;
forming a first RF circuit; and
forming a second RF circuit, wherein the first RF circuit is cascaded with the second RF circuit such that a section of an RF signal line connects the first RF circuit to the second RF circuit, wherein the section of the RF signal line is directly above the gap in the ground plane.
